(19) United States
(12) Patent Application Publication
(10) Pub. No.: US 2024/0412778 A1
(43) Pub. Date: Dec. 12, 2024

(54) MEMORY CELL, ARRAY READ-WRITE METHOD, CONTROL CHIP, MEMORY, AND ELECTRONIC DEVICE

(71) Applicant: BEIJING SUPERSTRING ACADEMY OF MEMORY TECHNOLOGY, Beijing (CN)

(72) Inventors: Zhengyong Zhu, Beijing (CN); Bokmoon Kang, Beijing (CN); Chao Zhao, Beijing (CN)

(73) Assignee: BEIJING SUPERSTRING ACADEMY OF MEMORY TECHNOLOGY, Beijing (CN)

(21) Appl. No.: 18/700,634

(22) PCT Filed: Dec. 21, 2022
(86) PCT No.: PCT/CN2022/140811

§ 371 Date: Apr. 11, 2024

(30) Foreign Application Priority Data
Jul. 7, 2022 (CN) 202210804363.5

(51) Int. Cl. G11C 11/4096; G11C 11/406; G11C 11/408; G11C 11/4094

(52) U.S. Cl. CPC G11C 11/4096; G11C 11/406; G11C 11/4085; G11C 11/4094

(57) ABSTRACT

A memory cell, an array read-write method, a control chip, a memory, and an electronic device. The memory cell comprises: a first transistor (TR_R) and a second transistor (TR_W); the first transistor comprises a first electrode, a second electrode, a third electrode, and a fourth electrode; the third electrode is a first gate, and the fourth electrode is a second gate; the second transistor comprises a fifth electrode, a sixth electrode, and a seventh electrode; the seventh electrode is a third gate; the first electrode is connected to a read bit line, the second electrode is connected to a reference signal, the first gate is connected to a read word line, the second gate is connected to the fifth electrode; the sixth electrode is connected to a write bit line, the third gate is connected to a write word line.

### CROSS-REFERENCE TO RELATED APPLICATIONS

The present application is a U.S. National Phase Entry of International Application No. PCT/CN2022/140811 having an international filing date of Dec. 21, 2022, which claims priority to Chinese Patent Application No. 202210804363.5 filed on Jul. 7, 2022, which are hereby incorporated herein by reference in their entireties.

### TECHNICAL FIELD

Some embodiments of the present disclosure relate to the field of semiconductors technologies, in particular to a storage cell, an array reading method and writing method, a control chip, a memory and an electronic device.

### BACKGROUND

A storage cell for a dynamic random access memory (DRAM) includes a transistor and a capacitor (as shown in FIG. 1, where SN is a Storage Node, BL is a Bit-line, WL is a Word-line, C is a capacitor, G is a gate of the transistor, S is a source of the transistor, and D is a drain of the transistor). However, due to leakage between channels, the stored data needs to be refreshed frequently, so it significantly increases power consumption.

### SUMMARY

The following is a summary of subject matters described herein in detail, and the summary is not intended to limit the protection scope.

Some embodiments of the present disclosure provide a storage cell, an array reading method and writing method, a control chip, a memory and an electronic device, which have very low leakage, can solve the problems of high refresh frequency and high power consumption in the existing storage cell, improve the performance of read/write operations, facilitate the setup of peripheral devices, and provide a technical basis for solving the crosstalk problem.

In some embodiments, a storage cell is provided, including: a first transistor configured as a read transistor; and, a second transistor configured as a write transistor.

The first transistor includes a first electrode, a second electrode, a third electrode and a fourth electrode; the third electrode is a first gate, and the fourth electrode is a second gate. The second transistor includes a fifth electrode, a sixth electrode and a seventh electrode; the seventh electrode is a third gate.

The first electrode is configured to be connected to a read bit-line, the second electrode is configured to be a reference voltage terminal for connecting a reference signal, the first gate is configured to be connected to a read word-line, and the second gate is configured to be connected to the fifth electrode.

The sixth electrode is configured to be connected to a write bit-line, and the third gate is configured to be connected to a write word-line.

In some embodiments, a storage array is provided, including: a write word-line; a read word-line; a write bit-line; a read bit-line; and, a plurality of storage cells.

The storage cell includes a first transistor and a second transistor; the first transistor includes a first electrode, a second electrode, a third electrode and a fourth electrode; the third electrode is a first gate, and the fourth electrode is a second gate.

The second transistor includes a fifth electrode, a sixth electrode and a seventh electrode; the seventh electrode is a third gate.

The first electrode is connected to the read bit-line, the second electrode can be configured as a reference voltage terminal for connecting a reference signal, the first gate is connected to the read word-line, and the second gate is connected to the fifth electrode.

The sixth electrode is connected to the write bit-line and the third gate is connected to the write word-line.

In some embodiments, a storage array is provided, including: a write word-line; a read word-line; a shared bit-line; and, a plurality of storage cells.

The storage cell includes a first transistor and a second transistor; the first transistor includes a first electrode, a second electrode, a third electrode and a fourth electrode; the third electrode is a first gate, and the fourth electrode is a second gate.

The second transistor includes a fifth electrode, a sixth electrode and a seventh electrode; the seventh electrode is a third gate.

Both the first electrode and the sixth electrode are connected to the shared bit-line, the second electrode may be configured as a reference voltage terminal for connecting a reference signal, the first gate is connected to the read word-line, and the second gate is connected to the fifth electrode.

The third gate is connected to the write word-line.

In some embodiments, a storage system is provided, including: a plurality of the aforementioned storage arrays; and, a plurality of amplifiers.

Each amplifier is an amplifier shared by two adjacent storage arrays; and the amplifier is configured to amplify the storage data read from the storage cell in the storage array, wherein the storage data is sensed in a sensing stage, and write the amplified stored data back to the storage node of the storage cell in a refresh stage.

In some embodiments, a data writing method is provided, based on the storage array described above. The method includes: in a storage cell, to which data needs to be written, in the storage array, inputting a gate voltage to a second transistor of the storage cell through a write word-line of the storage cell, so that the second transistor as a write transistor is turned on; and inputting a write voltage to the turned-on second transistor through a write bit-line or the shared bit-line of the storage cell, so that the write voltage is stored in a second gate of a first transistor connected to the second transistor, wherein the second gate is configured as a storage node of the storage cell, and the first transistor is a read transistor.

In some embodiments, a data reading method is provided, based on the storage array described above. The method includes: in a data read operation stage, inputting a first voltage to a read word-line connected to a first transistor of a storage cell, from which data needs to be read, in the storage array; wherein, the first voltage is between a first threshold voltage and a second threshold voltage, and the first threshold voltage is a turned-on threshold voltage for the first transistor when the storage cell stores data “1”; the second threshold voltage is a turned-on threshold voltage for the first transistor corresponding to when the storage cell stores data “0”; and
determining the read data of the storage cell to be 1 when a voltage change of the read bit-line connected to the first transistor is detected and a value of the change is greater than or equal to a preset first voltage change threshold, and determining the read data of the storage cell to be “0” when the voltage of the read bit-line connected to the first transistor does not change or a value of a change thereof is less than or equal to a preset second voltage change threshold.

In some embodiments, a control chip of a storage array is provided, and the control chip is configured to perform the data writing method described above.

In some embodiments, a control chip of a storage array is provided, and the control chip is configured to perform the data reading method described above.

In some embodiments, a memory is provided, including the storage array as described.

In some embodiments, an electronic device is provided, including the memory as described.

Beneficial effects of some embodiments of the present disclosure include: the read transistor includes a first gate and a second gate, and the second gate is connected to an electrode of the write transistor, the write transistor stores a write voltage in the electrode, omitting a capacitor, thus solving the problem of the requirement for a large capacitor, and correspondingly reducing the refresh frequency and power consumption; and because the gate of the read transistor has a back-gate effect, setting two gates facilitates the first gate to adjust the applied voltage according to the magnitude of the voltage of the second gate (which can be regarded as an assistant gate), to ensure the conduction between the source and drain of the first transistor, which improves the performance of read and write operations, facilitates the setting of peripheral devices, and provides a technical basis for solving the problem of crosstalk.

Other aspects may be understood upon reading and understanding the drawings and detailed description.

### BRIEF DESCRIPTION OF DRAWINGS

The accompanying drawings are used for providing understanding of technical solutions of the present disclosure, and form a part of the specification. They are used for explaining the technical solutions of the present disclosure together with the embodiments of the present disclosure, but do not form a limitation on the technical solutions of the present disclosure.

FIG. 1 is a schematic diagram of a storage cell of a 1T1C structure in the prior art.

FIG. 2 is a schematic diagram of a storage cell of a conventional 2T0C structure in the prior art.

FIG. 3 is a schematic diagram of a storage cell with a 2T0C structure according to some embodiments of the present disclosure.

FIG. 4 is a schematic diagram of threshold voltage shift of a gate of a transistor due to a back-gate effect in related art.

FIG. 5 is a schematic diagram of a storage cell with a 2T0C structure when a first electrode and a sixth electrode are combined into one electrode according to some embodiments of the present disclosure.

FIG. 6 is a flowchart of a data writing method for a storage cell according to some embodiments of the present disclosure.

FIG. 7 is a flowchart of a data reading method for a storage cell according to some embodiments of the present disclosure.

FIG. 8 is a schematic diagram of a structure of a storage array composed of storage cells with a 2T0C structure according to some embodiments of the present disclosure.

FIG. 9A is a schematic diagram of a structure of a storage array composed of storage cells with a 2T0C structure when a first electrode and a sixth electrode are combined into one electrode according to some embodiments of the present disclosure.

FIG. 9B is a schematic diagram of a structure of a storage array when a first electrode and a sixth electrode are not combined into one electrode and the connected read bit-line and write bit-line are combined outside the storage array according to some embodiments of the present disclosure.

FIG. 10A is a schematic diagram of a structure of a storage system according to some embodiments of the present disclosure.

FIG. 10B is a schematic partial enlarged diagram of a structure of another storage system according to some embodiments of the present disclosure.

FIG. 10C is a schematic diagram of connections when an amplifier is a current amplifier according to some embodiments of the present disclosure.

FIG. 11 is a flowchart of a data writing method for a storage array according to some embodiments of the present disclosure.

FIG. 12 is a flowchart of a data reading method for a storage array according to some embodiments of the present disclosure.

FIG. 13 is a flowchart of a data writing method for a storage system according to some embodiments of the present disclosure.

FIG. 14 is a flowchart of a data reading method for a storage system according to some embodiments of the present disclosure.

The realization of objectives, functional features and advantages of some embodiments of the present disclosure will be further explained in connection with the embodiments with reference to the accompanying drawings.

### DETAILED DESCRIPTION

Many embodiments are described herein, but the description is exemplary rather than restrictive, and it is apparent to those of ordinary skills in the art that there may be more embodiments and implementation solutions within the scope contained in the embodiments described herein. Although many possible combinations of features are shown in the accompanying drawings and discussed in specific implementations, many other combinations of the disclosed features are also possible. Unless expressly limited, any feature or element of any embodiment may be used in combination with, or may replace, any other feature or element in any other embodiment.

The present disclosure includes and contemplates combinations with features and elements known to those of ordinary skills in the art. The embodiments, features and elements that have been disclosed in the present disclosure may be combined with any conventional features or elements to form unique inventive solutions defined by the claims. Any feature or element of any embodiment may also be combined with a feature or an element from another inventive solution to form another unique inventive solution defined by the claims. Accordingly, it should be understood that any of the features shown and/or discussed in the present disclosure may be implemented alone or in any suitable combination. Therefore, the embodiments are not limited except the limitation by the appended claims and equivalents thereof. Moreover, various modifications and variations may be made within the protection scope of the appended claims.

Moreover, when representative embodiments are described, the specification may have presented a method and/or a process as a particular order of acts. However, the method or the process should not be limited to the acts with the specific order on a premise that the method or the process is independent of the specific order of the acts described herein. Those of ordinary skills in the art will understand that other orders of acts may also be possible. Therefore, the specific order of the acts illustrated in the specification should not be interpreted as a limitation on claims. In addition, the claims with respect to the method or process should not be limited to executing their acts according to the written order. Those skilled in the art may easily understand that these orders may change, and are still maintained in the spirit and scope of some embodiments of the disclosure.

Some embodiments of the present disclosure provide a novel logic circuit and related structural design, process flow and other solutions.

Under the basic framework that the described logic circuit is 2T0C, a read transistor has a double-gate structure, of which one gate is a control gate, and the other gate is used as a storage node to store a capacitor. At the same time, before data is written to a write transistor, a suitable voltage is applied to the read transistor, so that the read transistor is turned on when the data “1” is stored in the storage node and remains turned off when the data “0” is input.

The read operation of the above scheme is non-destructive, so that a write transistor with a lower leakage current may be used and the storage node does not need to store a higher capacitance to maintain the validity of the data.

In some embodiments, the write transistor may be a metal oxide semiconductor field effect transistor.

The above invention will be described in detail below by different embodiments.

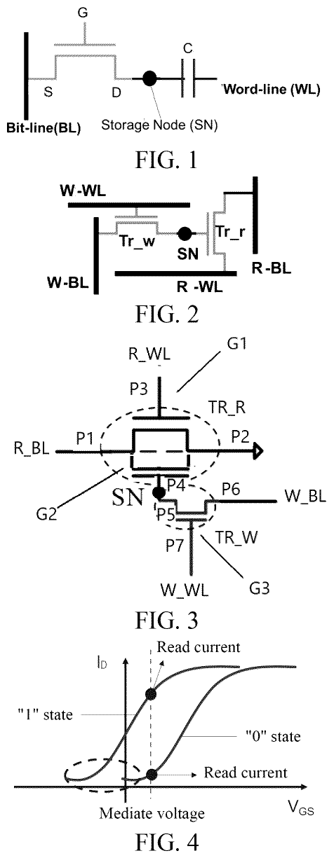

Some embodiments of the present disclosure provide a storage cell 1, as shown in FIG. 3, which may include: a first transistor TR_R configured as a read transistor; and, a second transistor TR_W configured as a write transistor.

Herein, the first transistor TR_R includes a first electrode P1, a second electrode P2, a third electrode P3 and a fourth electrode P4; the third electrode P3 is a first gate G1, and the fourth electrode P4 is a second gate G2 (back gate for short).

One of the first electrode P1 and the second electrode P2 is a source and the other is a drain.

The second transistor TR_W includes a fifth electrode P5, a sixth electrode P6 and a seventh electrode P7; and the seventh electrode P7 is a third gate G3.

One of the fifth electrode P5 and the sixth electrode P6 is a source and the other is a drain.

The first electrode P1 is configured to be connected to a read bit-line R_BL, and the second electrode P2 may be configured to be input with a reference voltage Vrefn for connecting a reference signal. The first gate G1 is configured to be connected to a read word-line R_WL, and the second gate G2 is configured to be connected to the fifth electrode P5.

The sixth electrode P6 is configured to be connected to a write bit-line W_BL, and the third gate G3 is configured to be connected to a write word-line W_WL.

In an exemplary embodiment of the present disclosure, the storage cell 1 also has a 2T0C structure, and compared to the conventional 2T0C structure shown in FIG. 2 (in which Tr_w is a write transistor and Tr_r is a read transistor), the read operation of the above scheme is non-destructive, so that a write transistor with a lower leakage current may be used, and the storage node does not need to store a higher capacitance to maintain the validity of the data. In addition, capacitance storage can be realized through the back gate, and the refresh frequency and power consumption of the storage cell can be simultaneously reduced through the write transistor with the lower leakage current.

In an exemplary embodiment of the present disclosure, the first transistor TR_R includes two gates, i.e., an assistant gate (i.e., a second gate, also referred to as a back gate) is added, the second gate is connected to the fifth electrode P5 of the write transistor (i.e., the second transistor TR_W), a voltage is provided by the fifth electrode P5, and the voltage provided by the fifth electrode P5 is set to a write voltage for storage of the write transistor.

In an exemplary embodiment of the present disclosure, the first gate G1 and the second gate G2 are gates independent of each other, and the first gate G1 is configured to control a read operation of the read transistor TR_R; the second gate G2 is configured to write data to a storage node through the write transistor TR_W as the storage node of the storage cell.

Since a gate of the transistor has a back-gate effect, as the write transistor writes a voltage to the fifth electrode P5, the assistant gate of the read transistor acquires a corresponding written voltage, and the gate of the read transistor will exhibit different threshold voltages (V_{TH}) depending on different written voltages of the assistant gate (e.g., high voltage or low voltage). As shown in FIG. 4, for the N-type read transistor TR_R, when the voltage of the assistant gate is high (for example, the written data is “1”), V_{TH} will shift negatively; and when the voltage of the assistant gate is low (for example, the written data is “0”), V_{TH} will shift positively.

In an exemplary embodiment of the present disclosure, after the first gate of the read transistor is given an appropriate voltage, it can be ensured that the read transistor is not turned on; when the data “O” is written to the assistant gate, the voltage is low, the threshold voltage of the read transistor shifts positively, the read transistor is even not be turned on. Therefore, the voltage on the read transistor BL (bit-line) does not change greatly, and may change slightly when leakage is considered, however the value of the change is less than the preset threshold. When data “1” is written, a corresponding high voltage is provided to the assistant gate, which negatively shifts the threshold voltage of the read transistor, and the read transistor is turned on. At this time, the BL of the read transistor is affected by the high voltage, and the voltage changes, and a value of the change exceeds the threshold. An SA circuit (a data reading circuit) is connected to the read bit-line, and whether the read data is 1 or 0 is determined by analyzing the amount of the voltage change on the read bit-line. In a process of reading 0 and 1, the voltage at the control gate (first gate) of the read transistor is unchanged, and the threshold voltage of the read transistor is changed by the voltage written at the assistant gate, so that the read transistor is automatically turned on or maintains off.

In some exemplary embodiments of the present disclosure, the first transistor TR_R is an N-type transistor; and, the second transistor TR_W is an N-type transistor or a P-type transistor.

In an exemplary embodiment of the present disclosure, the first transistor TR_R and the second transistor TR_W may both be N-type transistors, or both P-type transistors, or any one of them may be an N-type transistor, and the other may be a P-type transistor, the selection of the types for the first transistor TR_R and the second transistor TR_W is not limited herein, and may be self-defined according to requirements.

In an exemplary embodiment of the present disclosure, the first electrode P1, the second electrode P2, the fifth electrode P5, and the sixth electrode P6 may be set according to the type of the transistor selected. Here, it is not limited whether the first electrode P1, the second electrode P2, the fifth electrode P5 and the sixth electrode P6 are drains or sources, and they may be self-defined according to different scenes and requirements.

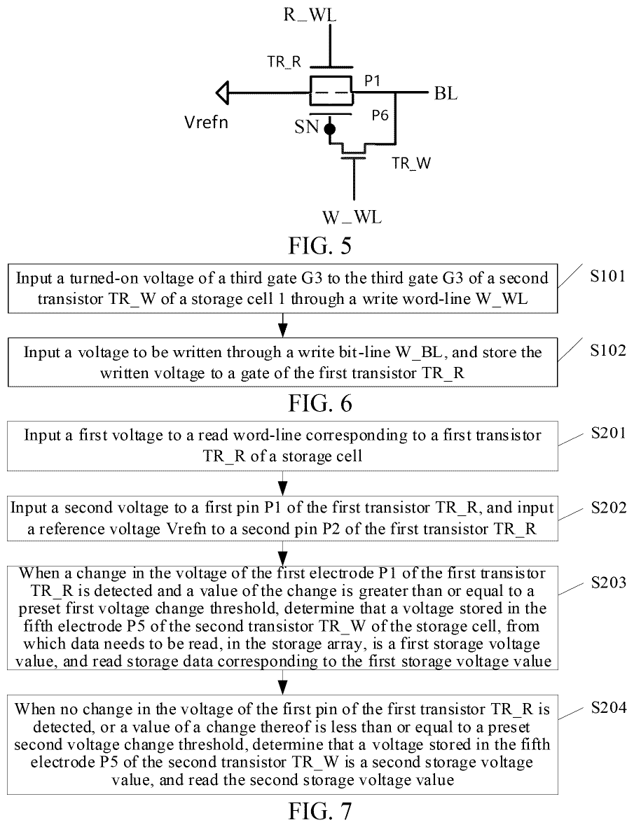

In an exemplary embodiment of the present disclosure, as shown in FIG. 5, the first electrode P1 and the sixth electrode P6 in a logic circuit share one electrode and are configured to be connected to different bit-lines or to the same bit-line.

In an exemplary embodiment of the present disclosure, the different bit-lines are the read bit-line and the write bit-line; the same bit-line serves as both the read bit-line and the write bit-line.

In an exemplary embodiment of the present disclosure, for a storage structure layout design, it is always desirable to reduce the numbers of BLs (bit-lines) and WLs (word-lines), particularly the number of the bit-lines BLs, to achieve a higher storage density.

In some embodiments, in the layout design, the BL to which the first electrode P1 and the sixth electrode P6 are connected shares one line in the storage array region.

In some embodiments, in the layout design, the BLs to which the first electrode P1 and the sixth electrode P6 are connected may be two lines in the storage array area, but one line in the peripheral area. Herein, a via is provided in the array area or the peripheral area, and the via connects the two lines.

In an exemplary embodiment of the present disclosure, compared with the traditional 2T0C structure, each storage cell in some embodiments of the present disclosure has only 3 signals, including 2 word-line signals and 1 bit-line signal, which facilitates the layout design, especially the layout design in a narrow space, and improves the practicability of the storage cell 1 according to some embodiments of the present disclosure.

In an exemplary embodiment of the present disclosure, the data writing method and the data reading method of the storage cell of the scheme according to some embodiments of the present disclosure are described in detail below.

In an exemplary embodiment of the present disclosure, as shown in FIG. 6, the data writing method of the storage cell may include acts S101-S102.

In S101, a turned-on voltage is input to a third gate G3 of a second transistor TR_W of a storage cell 1 through a write word-line W_WL;

In S102, a voltage to be written is input through a write bit-line W_BL, and the voltage is stored at a gate of a first transistor TR_R.

In an exemplary embodiment of the present disclosure, the voltage to be written may correspond to a voltage for storing data “1” or “0”, the write word-line W_WL is applied with a turned-on voltage of the second transistor, and the second transistor TR_W has a conduction between the fifth electrode P5 and the sixth electrode P6. After the voltage is written by the write bit-line W_BL, the voltage at the fifth electrode P5 is the same as the voltage at the sixth electrode P6 (connected to the write bit-line W_BL), both of which are the written voltage.

In an exemplary embodiment of the present disclosure, the method may further include: inputting a voltage, that is different from the turned-on voltage of the third gate G3, to the write word-line W_WL of the storage cell to which data does not need to be written, so that the second transistor TR_W of the storage cell 1 to which data does not need to be written is turned off.

In an exemplary embodiment of the present disclosure, for a plurality of storage cells 1 connected to the same write bit-line W_BL, when any one of the storage cells 1 needs to be written with data through the write bit-line W_BL, it needs to control the write word-lines W_WLs connected with the gates of the other storage cells 1 connected to the write bit-line W_BL to be applied with a voltage different from the turned-on voltage input by the third gate G3 of the storage cell 1 to which data needs to be written, so that the second transistor TR_W (write transistor) of the storage cell 1 to which data needs to be written is turned on, and the second transistors TR_W of the other storage cells to which data does not need to be written are turned off, ensuring that the data to be written is only written to the storage cell to which data needs to be written.

In an exemplary embodiment of the present disclosure, as shown in FIG. 7, the data reading method of the storage cell may include the following acts S201-S204:

In S201, a first voltage is input to the read word-line corresponding to the first transistor TR_R of the storage cell; the first voltage is between a first threshold voltage and a second threshold voltage, which are threshold voltages at which the first transistor may be turned on when data “1” and “0” are stored, respectively.

In an exemplary embodiment of the present disclosure, the first transistor TR_R serves as a read transistor, and when it is needed to read a voltage or a data signal stored at the back gate, a voltage may be input to the first gate G1 of the first transistor TR_R, so that the first electrode P1 and the second electrode P2 of the first transistor TR_R are turned off, thereby whether a voltage stored at the gate is a high voltage or a low voltage is determined according to the amount of change of the signal on the read bit-line. If the amount of change exceeds the threshold, the read data is “1”, and if there is no change, the read data is “0”.

In an exemplary embodiment of the present disclosure, the first gate G1 of the first transistor TR_R is connected to the read word-line R_WL, and the voltage of the first gate G1 may be provided through the read word-line R_WL. As can be seen from the foregoing discussion, a gate of the first transistor TR_R has a back-gate effect, when the stored write voltage is provided to the second gate G2 (assistant gate) of the first transistor TR_R through the fifth electrode P5, the threshold voltage of the gate of the first transistor TR_R shifts, and the shift varies depending on different data written by the fifth electrode P5 (such as “1” or “0”). Therefore, the voltage may be applied to the first gate G1 of the first transistor TR_R according to the magnitude of the voltage of the second gate G2, to ensure that the first transistor TR_R is turned off between the first electrode P1 and the second electrode P2, so that the first electrode P1 reads out the stored voltage.

In an exemplary embodiment of the present disclosure, the voltage applied to the first gate G1 of the first transistor TR_R may be between the first threshold voltage and the second threshold voltage, to supplement the voltage of the assistant gate, so that the first transistor TR_R is turned off. The first threshold voltage is a turned-on threshold voltage of the first transistor when data “1” is stored to the storage cell; and the second threshold voltage is a turned-on threshold voltage of the first transistor when data “O” is stored to the storage cell.

In S202, a second voltage is input to the first electrode P1 of the first transistor TR_R, and a reference voltage Vrefn is input to the second electrode P2 of the first transistor TR_R.

In an exemplary embodiment of the present disclosure, the read bit-line R_BL connected with the first electrode P1 may be pre-charged with a voltage (i.e., the second voltage) when initial reading of data is performed, the pre-charged voltage may be a voltage less than the power supply voltage VDD of the storage device, for example, may include, but is not limited to VDD/4, VDD/3, VDD/2, etc. The detailed value may be self-defined according to different application scenarios and requirements.

In an exemplary embodiment of the present disclosure, the reference voltage Vrefn may include, but is not limited to 0 V.

In S203, when a change in the voltage of the first electrode P1 of the first transistor TR_R is detected and a value of the change is greater than or equal to a preset first voltage change threshold, it is to determine that the voltage stored at the fifth electrode P5 of the second transistor TR_W of the storage cell from which data needs be read, in the storage array is a first storage voltage value, and the storage data corresponding to the first storage voltage value is read.

In an exemplary embodiment of the present disclosure, the first voltage change threshold may be self-defined according to different requirements or precision requirements, and is not limited in detail herein.

In an exemplary embodiment of the present disclosure, if the data “1” was previously written to the gate corresponding to the fifth electrode P5, a remarkable amount of conductance change (conduction current) may be measured between Vrefn and the selected read bit-line R_BL, and may be sensed at the selected read bit-line R_BL. Therefore, when a change in the voltage of the first electrode P1 of the first transistor TR_R is detected and a value of the change is greater than or equal to the preset first voltage change threshold, it may be determined that the stored write voltage is a high voltage, that is, the written data is “1”.

In S204, when no change in the voltage of the first electrode P1 of the first transistor TR_R is detected, or a value of the change thereof is less than or equal to a preset second voltage change threshold, it is to determine that the voltage stored at the fifth electrode P5 of the second transistor TR_W is a second storage voltage value, and the second storage voltage value is read; the second voltage change threshold is smaller than the first voltage change threshold.

In an exemplary embodiment of the present disclosure, the second voltage change threshold may be self-defined according to different requirements or precision requirements, and is not limited in detail herein.

In an exemplary embodiment of the present disclosure, if data “0” was previously written to the fifth electrode P5, no change in conductance is sensed between Vrefn and the selected read bit-line R_BL. Therefore, when no change in the voltage of the first electrode P1 of the first transistor TR_R is detected, or a value of the change thereof is less than or equal to a preset second voltage change threshold, it may be determined that the stored write voltage is a low voltage, that is, the write voltage is “0”.

In an exemplary embodiment of the present disclosure, the method may further include: during reading of the voltage value stored by the second transistor, inputting a voltage to a read word-line of a storage cell, from which data does not need to be read, in the storage array,
wherein the input voltage is different from an input voltage of a read word-line of a first transistor TR_R of a storage cell from which data needs to be read, so that the first transistor of the storage cell from which data does not need to be read is turned off.

It is known that the data writing and data reading of the conventional 2T0C cell structure (as shown in FIG. 2) are also separated, and are implemented with two transistors, Tr_w (write transistor) and Tr_r (read transistor), respectively. They need four signals, W-WL (write word-line) signal and W-BL (write bit-line) signal needed for the write operation, R-WL (read word-line) signal and R-BL (read bit-line) signal needed for the read operation, respectively. Compared to the conventional DRAM cells of 1T1C structure, the 2T0C structure in some embodiments of the present disclosure, due to the non-destructive read characteristics, also does not need too much capacitance between Tr_w and Tr_r. However, in conventional storage arrays with the 2T0C structure, it is a challenge to perform the read operation, because of the problem of crosstalk or current sharing between all 2T0C storage cells connected to R-WL (read word-line) and R-BL (read bit-line) connected to each 2T0C storage cell, and the DRAM community is still trying to solve this problem.

In an exemplary embodiment of the present disclosure, by inputting a voltage to the read word-line of the first transistor TR_R of a storage cell, from which data does not need to be read, in the storage array wherein the voltage is different from an input voltage of the read word-line of the first transistor TR_R of a storage cell from which data needs to be read, it is realized that only the first transistor TR_R of a storage cell from which data needs to be read is kept to be turned on, and the first transistor TR_R of a storage cell from which data does not need to be read is turned off, thereby solving the problems of current crosstalk and current sharing in the conventional 2T0C structure when data is read. For example, the problems of current sharing and crosstalk in a 2T0C battery can be easily solved by applying a low voltage to the read word-lines R_WL of unselected rows.

In an exemplary embodiment of the present disclosure, after the first transistor TR_R reads out the data corresponding to the first storage voltage value or the data corresponding to the second storage voltage value, the method may further include: inputting a turned-on voltage of the third gate G3 of the storage cell to a write word-line W_WL in the storage array; and inputting the read voltage value to a write bit-line W_BL corresponding to a storage cell to which data needs to be written, so as to refresh a voltage value stored in the second transistor TR_W.

In an exemplary embodiment of the present disclosure, in order to avoid the change of the written voltage caused by leakage, the written voltage may be rewritten to the write transistor for storage in time after each reading of the written voltage, so as to realize a timely refresh of the storage voltage.

In an exemplary embodiment of the present disclosure, the method may further include: during a process of refreshing the voltage value stored by the second transistor TR_W, inputting a voltage, different from the turned-on voltage of the third gate G3, to the write word-line of the storage cell in the storage array whose data does not need to be refreshed, so that the second transistor TR_W of the storage cell 1 to which data does not need to be written is turned off.

In an exemplary embodiment of the present disclosure, for a plurality of storage cells 1 connected to the same write bit-line, when any one of the storage cells 1 needs to be written with data through the write bit-line W_BL, it needs to control the write word-lines W_WLs connected with the gates of the other storage cells 1 connected to the write bit-line W_BL to be applied with a voltage different from the input voltage of the third gate G3 of the storage cell 1 to which data needs to be written, so that the second transistor TR_W (write transistor) of the storage cell 1 to which data needs to be written is turned on, and the second transistors TR_W of the other storage cells to which data does not need to be written are turned off, ensuring that the data to be written is only written to the storage cell 1 to which data needs to be written.

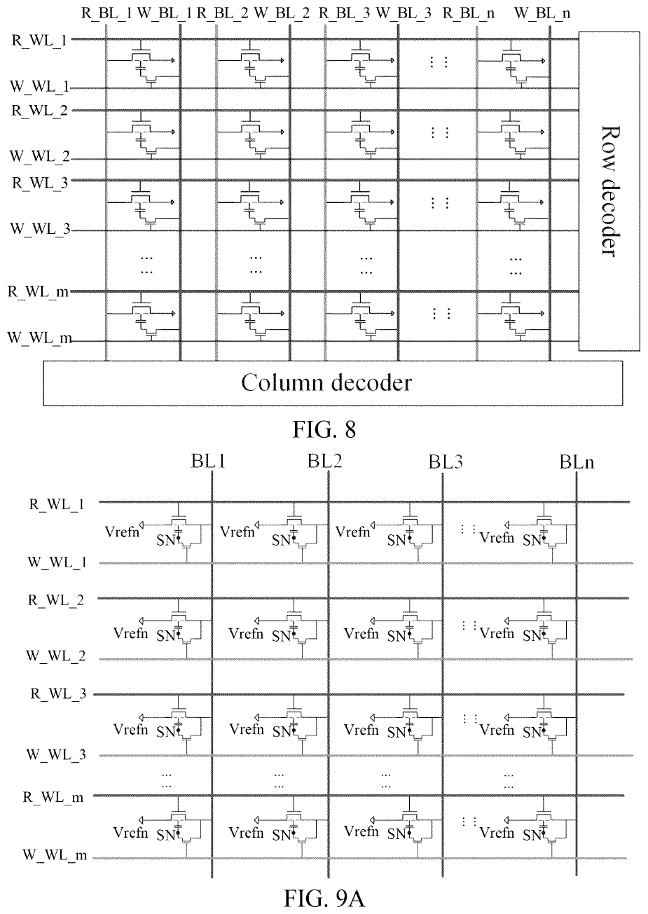

Some embodiments of the present disclosure also provide a storage array 2, as shown in FIG. 8, which may include: a write word-line W_WL; a read word-line R_WL; a write bit-line W_BL; a read bit-line R_BL; and, a plurality of the storage cells 1.

The storage cell 1 includes a first transistor TR_R and a second transistor TR_W; the first transistor TR_R includes a first electrode P1, a second electrode P2, a third electrode P3 and a fourth electrode P4; the third electrode P3 is a first gate G1, and the fourth electrode P4 is a second gate G2.

The second transistor TR_W includes a fifth electrode P5, a sixth electrode P6 and a seventh electrode P7; and the seventh electrode P7 is a third gate G3.

The first electrode P1 is connected to the read bit-line R_BL, the second electrode P2 is configured to input a reference voltage Vrefn, the first gate G1 is connected to the read word-line R_WL, and the second gate G2 is connected to the fifth electrode P5.

The sixth electrode P6 is connected to the write bit-line W_BL, and the third gate G3 is connected to the write word-line W_WL.

In an exemplary embodiment of the present disclosure, the write word-line W_WL and the read word-line R_WL may include a plurality of rows, for example, may include: W_WL_1, W_WL_2, W_WL_3, . . . , W_WL_m, and R_WL_1, R_WL_2, R_WL_3, . . . , R_WL_m, etc.

In an exemplary embodiment of the present disclosure, the read bit-line R_BL and the write bit-line W_BL may include a plurality of columns, for example, may include: R_BL_1, R_BL_2, R_BL_3, . . . , R_BL_n, and W_BL_1, W_BL_2, W_BL_3, . . . , W_BL_n, etc.

In an exemplary embodiment of the present disclosure, each storage cell 1 in the storage array 2 has a 2T0C structure, and compared with the conventional 2T0C structure shown in FIG. 2, it maintains the advantages of the conventional 2T0C structure, the read operation is lossless, has very low leakage, does not need a capacitor with a large capacitance, and Indium Gallium Zinc Oxide (IGZO) transistors may be used in the structure. Therefore, the 2T0C structure of the storage cell 1 according to some embodiments of the present disclosure solves the problem of the requirement for a large capacitance, and accordingly reduces the refresh frequency and power consumption.

In an exemplary embodiment of the present disclosure, unlike the conventional 2T0C structure, the read transistor (i.e., the first transistor TR_R) in the storage cell of the 2T0C structure according to some embodiments of the present disclosure includes two gates, i.e., an assistant gate (the second gate) is added, the second gate is connected to the fifth electrode P5 of the write transistor (i.e., the second transistor TR_W), is provided with a voltage by the fifth electrode P5, and the fifth electrode P5 is configured to store the write voltage of the write transistor. Since a gate of the transistor has a back-gate effect, as the write transistor writes a voltage to the fifth electrode P5, the assistant gate of the read transistor acquires a corresponding write voltage, and the gate of the read transistor will exhibit different threshold voltages (V_{TH}) depending on different write voltages of the assistant gate (e.g., high voltage or low voltage). As shown in FIG. 4, for the N-type read transistor TR_R, when the voltage of the assistant gate is high (for example, the written data is “1”), V_{TH} will shift negatively; and when the voltage of the assistant gate is low (for example, the written data is “0”), V_{TH} will shift positively.

In an exemplary embodiment of the present disclosure, after the first gate of the read transistor is given an appropriate voltage, it can be ensured that the read transistor is not turned on; when the data “0” is written to the assistant gate, the voltage is low, the threshold voltage of the read transistor shifts positively, the read transistor is even not be turned on. Therefore, the voltage on the read transistor BL (bit-line) does not change greatly, and may change slightly when leakage is considered, however the value of the change is less than the preset threshold. When data “1” is written, a corresponding high voltage is provided to the assistant gate, which negatively shifts the threshold voltage of the read transistor, and the read transistor is turned on. At this time, the BL of the read transistor is affected by the high voltage, and the voltage changes, and a value of the change exceeds the threshold. An SA circuit (a data reading circuit) is connected to the read bit-line, and whether the read data is “1” or “0” is determined by analyzing the amount of the voltage change on the read bit-line. In a process of reading “0” and “1”, the voltage at the control gate (first gate) of the read transistor is unchanged, and the threshold voltage of the read transistor is changed by the voltage written at the assistant gate (the second gate), so that the read transistor is automatically turned on or maintains off.

In an exemplary embodiment of the present disclosure, the first transistor TR_R is an N-type transistor or a P-type transistor; and, the second transistor TR_W is an N-type transistor or a P-type transistor.

In an exemplary embodiment of the present disclosure, the first transistor TR_R and the second transistor TR_W may both be N-type transistors, or both P-type transistors, or any one of them may be an N-type transistor and the other may be a P-type transistor, the selection of the types for the first transistor TR_R and the second transistor TR_W is not limited herein, and may be self-defined according to requirements.

In an exemplary embodiment of the present disclosure, the first electrode P1, the second electrode P2, the fifth electrode P5, and the sixth electrode P6 may be set according to the type of the transistor selected. Here, it is not limited whether the first electrode P1, the second electrode P2, the fifth electrode P5 and the sixth electrode P6 are drains or sources, and they can be self-defined according to different scenes and requirements.

In an exemplary embodiment of the present disclosure, the storage array 2 may further include a Row decoder and a Column decoder.

In some embodiments, the write word-line and the read word-line may be connected to the row decoder.

In some embodiments, the write bit-line and the read bit-line may be connected to the column decoder.

Some embodiments of the present disclosure also provide a storage array, which may include: a write word-line W_WL;
a read word-line R_WL;
a shared bit-line BL; and,
a plurality of the storage cells 1;

The storage cell 1 includes a first transistor TR_R and a second transistor TR_W; the first transistor TR_R includes a first electrode P1, a second electrode P2, a third electrode P3 and a fourth electrode P4; the third electrode P3 is a first gate, and the fourth electrode P4 is a second gate.

The second transistor TR_W includes a fifth electrode P5, a sixth electrode P6; the seventh electrode P7 is a third gate G3.

Both the first electrode P1 and the sixth electrode P6 are connected to the shared bit-line BL, the second electrode P2 is configured as a reference voltage terminal, the first gate G1 is connected to the read word-line R_WL, and the second gate G2 is connected to the fifth electrode P5.

The third gate G3 is connected to the write word-line W_WL.

In an exemplary embodiment of the present disclosure, in order to save the occupied area, the write bit-line and the read bit-line may be used in combination as a shared bit-line BL, which may include, but is not limited to, the following two schemes.

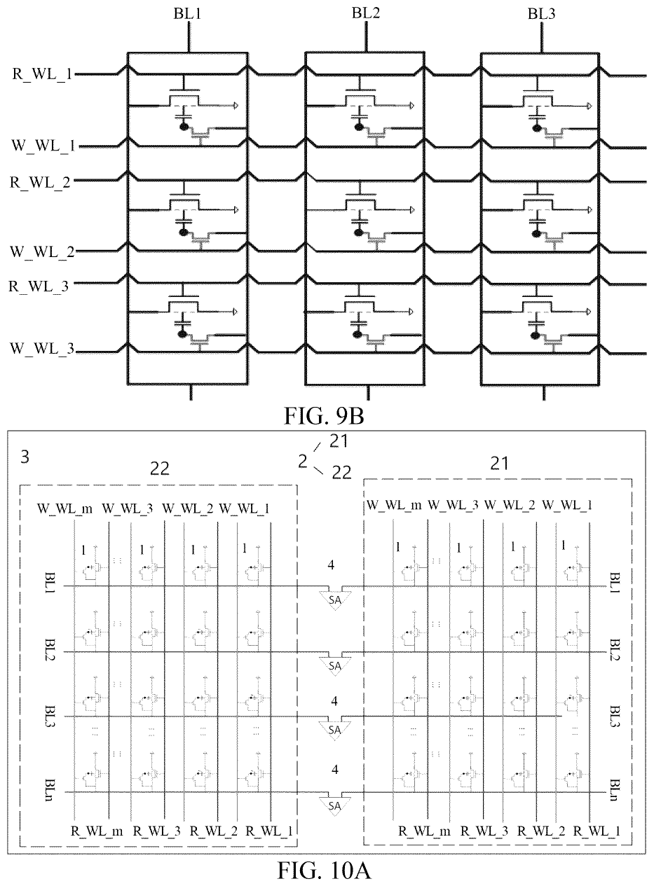

In an exemplary embodiment of the present disclosure, as shown in FIG. 9A, the first electrode P1 and the sixth electrode P6 are combined into one electrode, the write bit-line W_BL and the read bit-line R_BL are combined into one shared bit-line, and the electrode obtained after the combination is connected to the shared bit-line obtained after the combination.

In an exemplary embodiment of the present disclosure, as shown in FIG. 9B, the first electrode P1 and the sixth electrode P6 are not combined into one electrode within the storage cell, and the write bit-line W_BL and the read bit-line R_BL are combined into one shared bit-line outside the storage array.

In an exemplary embodiment of the present disclosure, for the convenience of drawings, the second gate of the storage cell in FIGS. 9A and 9B is represented by a capacitor symbol, but it does not mean that it is a capacitor here.

In an exemplary embodiment of the present disclosure, the write word-line W_WL and the read word-line R_WL may include a plurality of rows, for example, may include: W_WL_1, W_WL_2, W_WL_3, . . . , W_WL_m, and R_WL_1, R_WL_2, R_WL_3, . . . , R_WL_m, etc.

In an exemplary embodiment of the present disclosure, the shared bit-line BL may include a plurality of columns, for example, may include: BL1, BL2, BL3, . . . . BLn and the like.

In an exemplary embodiment of the present disclosure, for a storage structure layout design, it is always desirable to reduce the numbers of BLs (bit-lines) and WLs (word-lines), particularly the number of the bit-lines BLs, to achieve a higher storage density.

In an exemplary embodiment of the present disclosure, in order to reduce the number of bit-lines BLs, the first electrode P1 connected to the read bit-line R_BL may be connected to the sixth electrode P6 connected to the write bit-line W_BL, so that the first electrode P1 and the sixth electrode P6 are combined into one electrode, thus only one shared bit-line may be connected. In addition, the read bit-line R_BL and the write bit-line W_BL are combined into one shared bit-line BL outside the storage cell 1, so that the storage cell 1 of some embodiments of the present disclosure is connected to the external structure by one shared bit-line (BL) instead of the original two bit-lines (the read bit-line R_BL and the write bit-line W_BL), thus the two bit-lines (the read bit-line R_BL and the write bit-line W_BL) may be combined in an external region of the storage array where the current storage cell 1 is located.

In an exemplary embodiment of the present disclosure, the arrangement of the two bit-lines needs at least two vias configured to be connected over the silicon, which needs more area. Even if the storage cell is made small, the external circuit is too large to make a high-density memory, which may have a negative impact on the productization of the storage cell 1 of some embodiments of the present disclosure. However, in a scheme of some embodiments of the present disclosure, only one via is needed and the two bit-lines overlap by combining the read bit-line R_BL and the write bit-line W_BL into one bit-line BL, which improves the storage density.

In an exemplary embodiment of the present disclosure, compared with the traditional 2T0C structure, each storage cell in some embodiments of the present disclosure has only 3 signals, including 2 word-line signals and 1 bit-line signal, which facilitates the layout design, especially the layout design in a narrow space, and improves the practicability of the storage cell 1 according to some embodiments of the present disclosure.

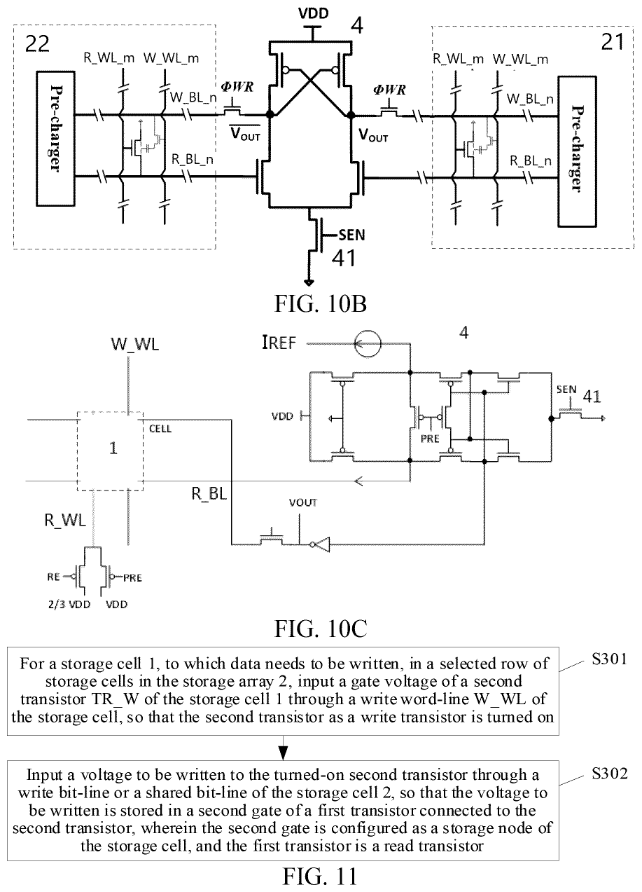

Some embodiments of the present disclosure also provide a storage system 3, as shown in FIGS. 10A, 10B, 10C, which may include: a plurality of the storage arrays 2; and, a plurality of amplifiers 4.

Herein, each of the amplifiers 4 is an amplifier 4 shared by two adjacent storage arrays; the amplifier 4 is configured to amplify the storage data read from the storage cell 1 in the storage array 2, wherein the storage data is sensed in the sensing stage, and write the amplified storage data back to the storage node of the storage cell 1 in a refresh stage.

In an exemplary embodiment of the present disclosure, the plurality of the storage arrays 2 include a first storage array 21 and a second storage array 22. Each read bit-line R_BL of the first storage array 21 and a different read bit-line R_BL of the second storage array 22 are jointly connected to the same amplifier 4 respectively, such that the storage cells 1 connected to the two read bit-lines R_BL connected to the same amplifier 4 share the same amplifier 4.

The two read bit-lines R_BL connected to the same amplifier 4 are respectively connected with different signal input terminals of the amplifier 4.

Write bit-lines W_BL corresponding to the two read bit-lines R_BL connected to the same amplifier 4 are respectively connected with different signal output terminals of the amplifier 4, and the read storage voltages are amplified by the amplifier 4, and then the amplified voltages are refreshed to the second transistor TR_W of the storage cell for storage.

In an exemplary embodiment of the present disclosure, when both the first storage array 21 and the second storage array 22 have in n (n is a positive integer) read bit-lines R_BL, n amplifiers 4 may be shared between the first storage array 21 and the second storage array 22. A first read bit-line R_BL in the first storage array 21 and a first read bit-line R_BL in the second storage array 22 may be connected to a same amplifier, a second read bit-line R_BL in the first storage array 21 and a second read bit-line R_BL in the second storage array 22 may be connected to the same amplifier 4, . . . , and so on, an n-th read bit-line R_BL in the first storage array 21 and an n-th read bit-line R_BL in the second storage array 22 may be connected to the same amplifier 4.

In an exemplary embodiment of the present disclosure, each amplifier 4 is configured to amplify a signal of the storage data read by the connected read bit-line R_BL.

In an exemplary embodiment of the present disclosure, the storage system 3 may further include a plurality of pre-chargers; and the plurality of pre-chargers may include a first pre-charger and a second pre-charger.

The write bit-line W_BL and the read bit-line R_BL corresponding to the first storage array 21 are both connected to the first pre-charger.

The write bit-line W_BL and the read bit-line R_BL corresponding to the second storage array 22 are both connected to the second pre-charger.

In an exemplary embodiment of the present disclosure, before signal amplification of a storage cell 1 connected to any read bit-line R_BL of the first storage array 21, the read bit-line R_BL may be pre-charged first, and a corresponding read bit-line R_BL in the second storage array 22 that shares the same amplifier 4 with the read bit-line R_BL may be pre-charged. The pre-charged voltage of the corresponding read bit-line R_BL in the second storage array 22 serves as a reference voltage of the read bit-line R_BL in the first storage array 21, and the pre-charged voltage value of the corresponding read bit-line R_BL in the second storage array 22 is smaller than the pre-charged voltage value of the read bit-line R_BL in the first storage array 21, for example, the pre-charged voltage value of the read bit-line R_BL of the first storage array 21 may be VDD, the pre-charged voltage value of the read bit-line R_BL in the second storage array 22 may include, but is not limited to VDD/2.

In an exemplary embodiment of the present disclosure, similarly, before signal amplification of the storage cell 1 connected to any one read bit-line R_BL of the second storage array 22, the read bit-line R_BL may be pre-charged first, and a corresponding read bit-line R_BL in the first storage array 21 that shares the same amplifier 4 with the read bit-line R_BL may be pre-charged. The pre-charged voltage of the corresponding read bit-line R_BL in the first storage array 21 serves as a reference voltage of the read bit-line R_BL in the second storage array 22, and the pre-charged voltage value of the corresponding read bit-line R_BL in the first storage array 21 is smaller than the pre-charged voltage value of the read bit-line R_BL in the second storage array 22, for example, the pre-charged voltage value of the read bit-line R_BL in the second storage array 22 may be VDD, the pre-charged voltage value of the read bit-line R_BL in the first storage array 21 may include, but is not limited to VDD/2.

In an exemplary embodiment of the present disclosure, each amplifier 4 may be provided with a starting switch 41. After the read bit-line R_BL is pre-charged, the storage data of a storage cell from which data is to be read on the read bit-line R_BL may be read using the read bit-line R_BL to be subjected to signal amplification. The starting switch 41 is turned on to input voltages on the two read bit-lines R_BL as differential signals to the two signal input terminals of the amplifier 4 to amplify, through a signal amplifier, signals on the read bit-line R_BL to be subjected to signal amplification.

In an exemplary embodiment of the present disclosure, before the read bit-line R_BL reads the storage data of the storage cell from which data is to be read, the read word-line R_WL connected to the first transistor TR_R of the storage cell from which data is to be read may be controlled to be input with a high voltage, and the read word-line R_WL connected to the first transistor TR_R of the storage cell from which data does not need to be read may be controlled to be input with a low voltage, so that the first transistor TR_R of the storage cell from which data does not need to be read is turned off, thereby solving the problems of current crosstalk and current sharing in a conventional 2T0C structure when data is read. That is, the problems of current sharing and crosstalk in a 2T0C battery can be easily solved by applying a low voltage to the read word-lines R_WL of unselected rows.

In an exemplary embodiment of the present disclosure, after the signal of the data read on the read bit-line R_BL is amplified, the amplified signal may also be input to the write bit-line W_BL connected to the storage cell 1 from which data is to be read through the signal output terminal of the amplifier, to rewrite the amplified read data into the second transistor TR_W of the storage cell 1 from which data is to be read through the write bit-line W_BL, so as to realize the refresh of the storage data in the second transistor TR_W of the storage cell 1 from which data is to be read, and to avoid the occurrence of an error in the storage data due to leakage.

In an exemplary embodiment of the present disclosure, before the storage data in the second transistor TR_W of the storage cell 1 from which data is to be read is refreshed, the write word-line W_WL of the second transistor TR_W of the storage cell 1 from which data is to be read is controlled to be input with a high voltage, and the write word-line W_WL of the second transistor TR_W of the storage cell 1 from which data does not need to be read is controlled to be input with a low voltage, so that the second transistor TR_W of the storage cell 1 from which data does not need to be read is turned off, thereby avoiding refresh the storage data of the second transistor TR_W of the storage cell 1 from which data is to be read into the second transistor TR_W of the storage cell 1 from data does not need to be read in the process of data refresh, and improving the reliability of data storage.

In an exemplary embodiment of the present disclosure, the storage array in the storage system may be composed of storage cells of a 2T0C structure in which electrodes are combined according to some embodiments of the present disclosure (as shown in FIG. 10A, or it may also be composed of storage cells of a 2T0C structure in which the electrodes are not combined (a full-view diagram is not drawn herein, the structure is similar to that of FIG. 10A, except that the first electrode P1 and the sixth electrode P6 of each storage cell are not combined, and reference may be made to a corresponding storage array, and a partial schematic view is shown in FIG. 10B). In addition, the storage array may also be a storage array in which electrodes of each storage cell are not combined, and the bit-lines to which the first electrode and the sixth electrode are connected outside the storage array are combined (the schematic diagram is not shown here, and for a storage system, reference may be made to FIG. 9B and FIG. 10A as long as the storage array in FIG. 10A is replaced by the storage array in FIG. 9B).

In an exemplary embodiment of the present disclosure, the amplifier may be a voltage amplifier or a current amplifier.

The input terminals of the two differential input signals of the amplifier are respectively connected with two different read bit-lines, and the two different read bit-lines are respectively from the adjacent storage arrays.

One of the input terminals of the two differential input signals is an input terminal of the storage data read by the read bit-line, and the other input terminal is a reference signal terminal of the differential input signals of the amplifier.

In an exemplary embodiment of the present disclosure, the amplifier 4 may be a voltage amplifier or a current amplifier, or may be self-selected as required. FIG. 10C is a schematic diagram of connections when the amplifier is a current amplifier, where I_{REF} is a reference current, similar to the example shown in FIG. 10B, and this reference current may be provided by another storage array.

In an exemplary embodiment of the present disclosure, in one storage system, the above-mentioned three types of storage arrays may be used in any combination, and there is no limitation on the detailed combination scheme and the number of combinations.

In an exemplary embodiment of the present disclosure, for the convenience of drawing, the second gates of the storage cells in FIGS. 10A and 10B are each represented by a capacitor.

Some embodiments of the present disclosure provide a data writing method that is based on the storage array. As shown in FIG. 11, the method may include the following acts S301-S302:

In S301, for a storage cell 1, to which data needs to be written, in a selected row of storage cells in the storage array 2, a gate voltage of a second transistor TR_W of the storage cell 1 is input through a write word-line W_WL of the storage cell, so that the second transistor as a write transistor is turned on.

In S302, a write voltage is input to the turned-on second transistor through a write bit-line or the shared bit-line of the storage cell 2, so that the write voltage is stored in a second gate of a first transistor connected to the second transistor, wherein the second gate is configured as a storage node of the storage cell, and the first transistor is a read transistor.

In an exemplary embodiment of the present disclosure, the write voltage may be a high voltage or a low voltage, the corresponding storage data is “1” or “0”, the write word-line W_WL is applied with a high voltage (i.e., the turned-on voltage of the third gate G3), and the second transistor TR_W has a conduction between the fifth electrode P5 and the sixth electrode P6. After the voltage is written by the write bit-line W_BL, the voltage at the fifth electrode P5 is the same as the voltage at the sixth electrode P6 (connected to the write bit-line W_BL), both of which are the write voltage.

In an exemplary embodiment of the present disclosure, the method may further include: inputting a voltage, different from the turned-on voltage of the third gate G3 of the selected row of storage cells, to the write word-line W_WL of each unselected row of storage cells 1 in the storage array 2, so that the second transistor TR_W of the storage cell 1 to which data does not need to be written is turned off.

In an exemplary embodiment of the present disclosure, for a plurality of storage cells 1 connected to the same write bit-line W_BL in the storage array 2, when any one of the storage cells 1 needs to be written with data through the write bit-line W_BL, it needs to control the write word-lines W_WL connected with the gates of the other storage cells 1 connected to the write bit-line W_BL to be applied with a voltage different from the turned-on voltage input from the third gate G3 of the storage cell 1 to which data needs to be written, so that the second transistor TR_W (write transistor) of the storage cell 1 to which data needs to be written is turned on, and the second transistors TR_W of the other storage cells to which data does not need to be written are turned off, ensuring that the data to be written is only written to the storage cell to which data needs to be written.

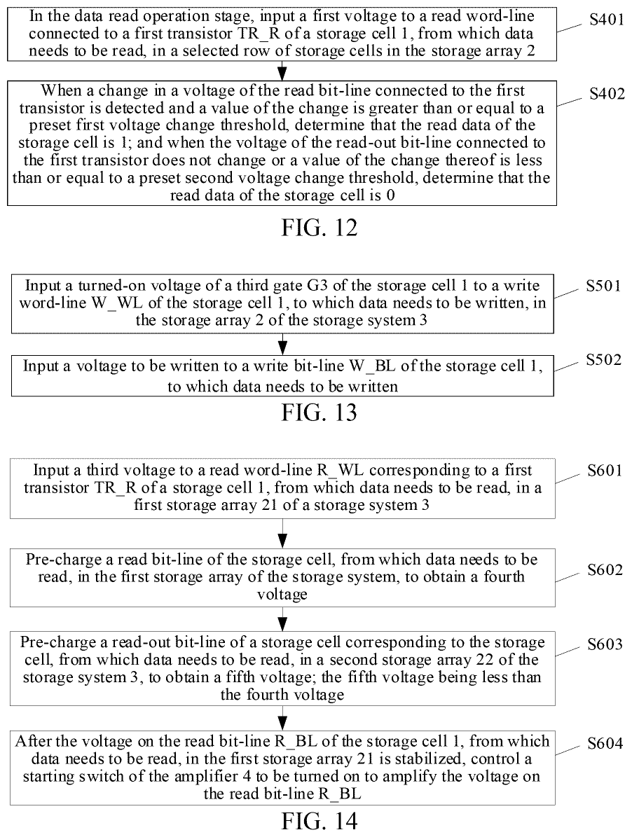

Some embodiments of the present disclosure provide a data reading method that is based on the storage array. As shown in FIG. 12, the data reading method may include the following acts S401-S402.

In S401, in a data read operation stage, a first voltage is input to a read word-line connected to a first transistor TR_R of a storage cell 1, from which data needs to be read, in a selected row of storage cells in the storage array 2; wherein, the first voltage is between a first threshold voltage and a second threshold voltage, which are threshold voltages at which the first transistor may be turned on when data “1” and “0” are stored, respectively.

In an exemplary embodiment of the present disclosure, the first transistor TR_R serves as a read transistor, and when a voltage stored in the second transistor TR_W needs to be read, a voltage may be input to the first gate G1 of the first transistor TR_R, so that the first electrode P1 and the second electrode P2 of the first transistor TR_R are turned off, thereby whether a voltage that is stored in the fifth electrode P5 is a high voltage or a low voltage or whether the stored data is “1” or “0” is determined according to the magnitude of the voltage (and/or current magnitude) of the first electrode P1.

In an exemplary embodiment of the present disclosure, the first gate G1 of the first transistor TR_R is connected to the read word-line R_WL, and the voltage (first voltage) of the first gate G1 may be provided through the read word-line R_WL. As can be seen from the foregoing discussion, a gate of the first transistor TR_R has a back-gate effect, when the stored write voltage is provided to the second gate G2 (assistant gate) of the first transistor TR_R through the fifth electrode P5, the threshold voltage of the gate of the first transistor TR_R shifts, and the shift varies depending on the different data written by the fifth electrode P5 (such as “1” or “0”). Therefore, a voltage may be applied to the first gate G1 of the first transistor TR_R according to the magnitude of the voltage of the second gate G2, to ensure that the first transistor TR_R is turned off between the first electrode P1 and the second electrode P2, so that the first electrode P1 reads out the stored data.

In an exemplary embodiment of the present disclosure, a voltage applied to the first gate G1 of the first transistor TR_R may be between a low voltage and a high voltage (“0”−“1”), to supplement the voltage of the assistant gate, so that the first transistor TR_R is turned on.

In S402, the read data of the storage cell is determined to be “1” when a change in the voltage the read bit-line connected to the first transistor is detected and a value of the change is greater than or equal to a preset first voltage change threshold, and the read data of the storage cell is determined to be “0” when the voltage of the read bit-line connected to the first transistor does not change or a value of the change in the voltage of the read bit-line connected to the first transistor is less than or equal to a preset second voltage change threshold.

In an exemplary embodiment of the present disclosure, a pre-charging stage is further included before the data read operation stage, and the method may further include: pre-charging the read bit-line or the shared bit-line, so that a voltage on the read bit-line is higher than a voltage provided at a reference signal terminal in differential input signal input terminals of an amplifier. In an exemplary embodiment of the present disclosure, the read bit-line R_BL connected with the first electrode P1 may be pre-charged with a voltage (i.e., the second voltage) when initial reading of data is performed, the pre-charged voltage may be a voltage less than the power supply voltage VDD of the storage device, for example, may include, but is not limited to VDD/4, VDD/3, VDD/2, etc. The detailed value may be self-defined according to different application scenarios and requirements.

In an exemplary embodiment of the present disclosure, the reference voltage may include, but is not limited to, 0 V.

In an exemplary embodiment of the present disclosure, when a change in the voltage of the first electrode P1 of the first transistor is detected and a value of the change is greater than or equal to a preset first voltage change threshold, a voltage stored at a fifth electrode of a second transistor of a storage cell in the storage array from which data needs to be read is determined as a first storage voltage value, and the first storage voltage value is read.

In an exemplary embodiment of the present disclosure, the first voltage change threshold may be self-defined according to different requirements or precision requirements, and is not limited in detail herein.

In an exemplary embodiment of the present disclosure, if the data “1” was previously written to the fifth electrode P5, a remarkable amount of conductance change (conduction current) may be measured between Vrefn (e.g., 0 potential or a ground terminal) and the selected read bit-line R_BL, and may be sensed at the selected read bit-line R_BL. Therefore, when a change in the voltage of the first electrode P1 of the first transistor TR_R is detected and a value of the change is greater than or equal to the preset first voltage change threshold, it may be determined that the stored write voltage is a high voltage, that is, the written data is “1”.

In an exemplary embodiment of the present disclosure, when no change in the voltage of the first electrode of the first transistor TR_R is detected, or a value of the change thereof is less than or equal to a preset second voltage change threshold, the voltage stored at the fifth electrode P5 of the second transistor TR_W is determined as a second storage voltage value, and the second storage voltage value is read; and the second voltage change threshold is smaller than the first voltage change threshold.

In an exemplary embodiment of the present disclosure, the second voltage change threshold may be self-defined according to different requirements or precision requirements, and is not limited in detail herein.

In an exemplary embodiment of the present disclosure, if data “O” was previously written to the fifth electrode P5, no conductance is sensed between Vrefn and the selected read bit-line R_BL. Therefore, when no change in the voltage of the first electrode P1 of the first transistor TR_R is detected, or a value of the change thereof is less than or equal to a preset second voltage change threshold, the stored write voltage is determined as a low voltage, that is, the write voltage is “0”.

In an exemplary embodiment of the present disclosure, the method may further include: during reading of a voltage value stored by a second transistor TR_W in any storage cell 1 in the storage array 2, inputting a voltage to a read word-line R_WL of a storage cell 1, from which data does not need to be read, in the storage array 2, wherein the input voltage is different from an input voltage of a read word-line R_WL of a first transistor TR_R of the storage cell 1 from which data needs to be read, so that the first transistor TR_R of the storage cell 1 from which data does not need to be read is turned off; wherein, the read word-line of the storage cell from which data does not need to be read is different from the read word-line of the first transistor of the storage cell from which data needs to be read.

It is known that the data writing and data reading of the conventional 2T0C cell structure (as shown in FIG. 2) are also separated, and are implemented with two transistors, Tr_w (write transistor) and Tr_r (read transistor), respectively. They need four signals, W-WL (write word-line) signal and W-BL (write bit-line) signal needed for the write operation, R-WL (read word-line) signal and R-BL (read bit-line) signal needed for the read operation, respectively. Compared to the conventional DRAM cells of 1T1C structure, the 2T0C structure in some embodiments of the present disclosure, due to the non-destructive read characteristics, also does not need too much capacitance between Tr_w and Tr_r. However, in storage arrays with the 2T0C structure, it is a challenge to perform the read operation, because of the problem of crosstalk or current sharing between all 2T0C storage cells connected to R-WL (read word-line) and R-BL (read bit-line) connected to each 2T0C storage cell, and the DRAM community is still trying to solve this problem.

In an exemplary embodiment of the present disclosure, a voltage is input to a read word-line R_WL of the first transistor TR_R of the storage cell 1, from which data does not need to be read, in the storage array 2, wherein the input voltage is different from the input voltage of the read word-line R_WL of the first transistor TR_R of the storage cell 1 from which data needs to be read, so that the first transistor TR_R of the storage cell 1 from which data does not need to be read is turned off, thereby solving the problems of current crosstalk and current sharing in a conventional 2T0C structure when data is read. For example, the problems of current sharing and crosstalk in a 2T0C battery can be easily solved by applying a low voltage to the read word-lines R_WL of unselected rows.

In an exemplary embodiment of the present disclosure, the method may further include: performing data refresh in a refresh stage. The performing data refresh in a refresh stage may include: sensing storage data in the storage cell, amplifying the storage data by the amplifier, and writing the amplified storage data back to a storage node of the storage cell.

In an exemplary embodiment of the present disclosure, after the first transistor TR_R reads out the first storage voltage value or the second storage voltage value, a turned-on voltage of the third gate G3 of the storage cell is input to a write word-line W_WL in the storage array. The read voltage value is input into a write bit-line W_BL corresponding to the storage cell 1 to which data needs to be written, so as to refresh the voltage value stored in the second transistor TR_W.

In an exemplary embodiment of the present disclosure, in order to avoid the change of the written voltage caused by leakage, the written voltage may be rewritten to the write transistor for storage in time after each reading of the written voltage, so as to realize a timely refresh of the storage voltage.

In an exemplary embodiment of the present disclosure, the method may further include: during a process of refreshing the storage data of the second transistor TR_W, inputting a voltage to a write word-line W_WL of the storage cell 1, whose stored data does not need to be refreshed, in the storage array 2, so that the second transistor TR_W of the storage cell 1 to which data does not need to be written is turned off; wherein the write word-line connected to the storage cell that needs to be refreshed is different from the write word-line of the storage cell whose stored data does not need to be refreshed.

In an exemplary embodiment of the present disclosure, for a plurality of storage cells 1 connected to the same write bit-line, when any one of the storage cells 1 needs to be written with data through the write bit-line W_BL, it needs to control the write word-line W_WL connected with the gates of the other storage cells 1 connected to the write bit-line W_BL to be applied with a voltage different from the input voltage of the third gate G3 of the storage cell 1 to which data needs to be written, so that the second transistor TR_W (write transistor) of the storage cell 1 to which data needs to be written is turned on, and the second transistors TR_W of the other storage cells to which data does not need to be written are turned off, ensuring that the data to be written is only written to the storage cell 1 to which data needs to be written.

Some embodiments of the present disclosure provide a data writing method that is based on the storage system. As shown in FIG. 13, the data writing method may include the following acts S501-S502.

In S501, a turned-on voltage of the third gate G3 of the storage cell 1 is input to the write word-line W_WL of the storage cell 1, to which data needs to be written, in the storage array 2 of the storage system 3.

In S502, a voltage to be written is input to the write bit-line W_BL of the storage cell 1 to which data needs to be written.

In an exemplary embodiment of the present disclosure, the data to be written may be “1” or “0”, the write word-line W_WL is applied with a high voltage (i.e., the turned-on voltage of the third gate G3), and the second transistor TR_W has a conduction between the fifth electrode P5 and the sixth electrode P6. After the voltage is written by the write bit-line W_BL, the voltage at the fifth electrode P5 is the same as the voltage at the sixth electrode P6 (connected to the write bit-line W_BL), both of which are the written voltage.

In an exemplary embodiment of the present disclosure, the method may further include: inputting a voltage at the write word-line W_WL of the storage cell 1, to which data does not need to be written, in the storage array 2 of the storage system 3, wherein the input voltage is different from the turned-on voltage of the third gate G3, so that the second transistor TR_W of the storage cell 1 to which data does not need to be written is turned off.

In an exemplary embodiment of the present disclosure, for a plurality of storage cells 1 connected to the same write bit-line W_BL in the storage array 2, when any one of the storage cells 1 needs to be written with data through the write bit-line W_BL, it needs to control the write word-line W_WL connected with the gates of the other storage cells 1 connected to the write bit-line W_BL to be applied with a voltage different from the turned-on voltage input from the third gate G3 of the storage cell 1 to which data needs to be written, so that the second transistor TR_W (write transistor) of the storage cell 1 to which data needs to be written is turned on, and the second transistors TR_W of the other storage cells to which data does not need to be written are turned off, ensuring that the data to be written is only written to the storage cell to which data needs to be written.

Some embodiments of the present disclosure provide a data reading method that is based on the storage system. As shown in FIG. 14, the data reading method may include the following S601-S605.

In S601, a third voltage is input to a read word-line R_WL corresponding to a first transistor TR_R of a storage cell 1, from which data needs to be read, in the first storage array 21 of the storage system 3; wherein the third voltage is located between a first threshold voltage and a second threshold voltage; the first threshold voltage is a threshold voltage that enables the read transistor to be turned on when the storage data of the storage node is 1; the second threshold voltage is a threshold voltage that enables the read transistor to be turned on when the storage data of the storage node is 0.

In an exemplary embodiment of the present disclosure, the first transistor TR_R serves as a read transistor, and when a voltage stored in the second transistor TR_W needs to be read, a voltage may be input to the first gate G1 of the first transistor TR_R, so that the first transistor TR_R is turned on between the first electrode P1 and the second electrode P2, thereby whether a voltage stored by the fifth electrode P5 is a high voltage or a low voltage or whether the stored data is “1” or “0” is determined according to the magnitude of the voltage (and/or current magnitude) of the first electrode P1.

In an exemplary embodiment of the present disclosure, the first gate G1 of the first transistor TR_R is connected to the read word-line R_WL, and the voltage (third voltage) of the first gate G1 may be provided through the read word-line R_WL. As can be seen from the foregoing discussion, a gate of the first transistor TR_R has a back-gate effect, when the stored write voltage is provided to the second gate G2 (assistant gate) of the first transistor TR_R through the fifth electrode P5, the threshold voltage of the gate of the first transistor TR_R shifts, and the shift varies depending on the different data written by the fifth electrode P5 (such as 1 or 0). Therefore, the voltage may be applied to the first gate G1 of the first transistor TR_R according to the magnitude of the voltage of the second gate G2, to ensure that the first transistor TR_R is turned off between the first electrode P1 and the second electrode P2, so that the first electrode P1 reads out the stored voltage.

In an exemplary embodiment of the present disclosure, a voltage applied to the first gate G1 of the first transistor TR_R may be between a low voltage and a high voltage (“0”-“1”), to supplement the voltage of the assistant gate, so that the first transistor TR_R is turned on.

In S602, the read bit-line of the storage cell, from which data needs to be read, in the first storage array of the storage system is pre-charged, to obtain a fourth voltage.

In an exemplary embodiment of the present disclosure, before signal amplification of a storage cell 1 connected to any read bit-line R_BL of the first storage array 21, the read bit-line R_BL may be pre-charged first, to obtain a fourth voltage, the voltage value of which may be VDD.

In S603, the read bit-line of the storage cell corresponding to the storage cell, from which data needs to be read, in the second storage array 22 of the storage system 3 is pre-charged to obtain a fifth voltage; wherein the fifth voltage is less than the fourth voltage.

In an exemplary embodiment of the present disclosure, a corresponding read bit-line R_BL in the second storage array 22 sharing the same amplifier 4 as the pre-charged read bit-line R_BL in the first storage array 21 is pre-charged to obtain a fifth voltage; the pre-charged voltage of the corresponding read bit-line R_BL in the second storage array 22 serves as a reference voltage of the read bit-line R_BL in the first storage array 21, and the voltage value of the fifth voltage may include, but is not limited to, VDD/2.

In S604, after the voltage on the read bit-line R_BL of the storage cell 1, from which data needs to be read, in the first storage array 21 is stabilized, the starting switch of the amplifier 4 is controlled to be turned on to amplify the voltage on the read bit-line R_BL.

In an exemplary embodiment of the present disclosure, when the storage data in the second transistor TR_W is 0, the pre-charged fourth voltage does not change after the data is read. When the storage data in the second transistor TR_W is 1, the pre-charged fourth voltage first decreases after the data is read, when the fourth voltage no longer decreases, a voltage stable state is reached, and it is determined that the reading of the data is completed. At this time, the starting switch of the amplifier 4 may be turned on, the voltages on the current two read bit-lines are input to the amplifier 4, and the decreased and stabilized fourth voltage (as the readout data) is amplified by the amplifier 4.

In an exemplary embodiment of the present disclosure, before the read bit-line R_BL reads the storage data of the storage cell from which data is to be read, the read word-line R_WL connected to the first transistor TR_R of the storage cell from which data is to be read may be controlled to input a high voltage, and the read word-line R_WL connected to the first transistor TR_R of the storage cell from which data does not need to be read may be controlled to input a low voltage, so that the first transistor TR_R of the storage cell from which data does not need to be read is turned off, thereby solving the problems of current crosstalk and current sharing in a conventional 2T0C structure when data is read. That is, the problems of current sharing and crosstalk in the 2T0C circuit of some embodiments of the present disclosure can be easily solved by applying a low voltage to the read word-lines R_WL of unselected rows.

In S605, the amplified voltage is read through the first signal output terminal of the amplifier 4, to serve as the storage voltage of the storage cell, from which data needs to be read, in the first storage array 21.

In an exemplary embodiment of the present disclosure, after the amplified voltage is read through the first signal output terminal of the amplifier 4, the method may further include: inputting a turned-on voltage of a third gate G3 of the second transistor TR_W to a write word-line corresponding to the storage cell, from which data needs to be read, in the first storage array 21; and inputting the read amplified voltage into a write bit-line corresponding to the second transistor TR_W of the storage cell from which data needs to be read, so as to refresh the voltage value stored by the second transistor TR_W of the storage cell from which data needs to be read.

In an exemplary embodiment of the present disclosure, after the signal of the readout data on the read bit-line R_BL is amplified, the amplified signal may also be input to the write bit-line W_BL connected to the storage cell 1 from which data is to be read through the signal output terminal of the amplifier, to rewrite the amplified readout data into the second transistor TR_W of the storage cell 1 from which data is to be read through the write bit-line W_BL, so as to realize the refresh of the stored data in the second transistor TR_W of the storage cell 1 from which data is to be read, and to avoid the occurrence of an error in the stored data due to leakage.

In an exemplary embodiment of the present disclosure, the method may further include: during the process of refreshing the voltage value stored by the second transistor TR_W of the storage cell from which data needs to be read, inputting a voltage different from the turned-on voltage of the third gate G3 of the second transistor TR_W to the write word-line W_WL of the storage cell, whose data does not need to be refreshed, in the first storage array 21, so that the second transistor TR_W of the storage cell 1 to which data does not need to be written is turned off.

In an exemplary embodiment of the present disclosure, before the stored data in the second transistor TR_W of the storage cell 1 from which data is to be read is refreshed, the write word-line W_WL of the second transistor TR_W of the storage cell 1 from which data is to be read is controlled to be input with a high voltage, and the write word-line W_WL of the second transistor TR_W of the storage cell 1 from which data does not need to be read is controlled to be input with a low voltage, so that the second transistor TR_W of the storage cell 1 from which data does not need to be read is turned off, thereby avoiding refresh of the stored data of the second transistor TR_W of the storage cell 1 from which data is to be read into the second transistor TR_W of the storage cell 1 from which data does not need to be read in the process of data refresh, and improving the reliability of data storage.

Some embodiments of the present disclosure provide a control chip of a storage array, configured to perform a data writing method based on the storage array and a data reading method based on the storage array.

In an exemplary embodiment of the present disclosure, any of the aforementioned embodiments of the storage cell, the storage array and the data writing and data reading method thereof are applicable to the control chip embodiment of the storage array, and will not be repeated here.

Some embodiments of the present disclosure provide a control chip of a storage system, configured to perform a data writing method based on the storage array.

Some embodiments of the present disclosure provide a control chip of a storage system, configured to perform a data reading method based on the storage array.

In an exemplary embodiment of the present disclosure, any of the aforementioned embodiments of the storage cell, the storage array and the data writing and data reading method thereof are applicable to the control chip embodiments of the storage system, and will not be repeated here.

Some embodiments of the present disclosure provide a memory including the storage array.

In an exemplary embodiment of the present disclosure, any of the aforementioned embodiments of the storage cell, the storage array and the data writing and data reading method thereof are applicable to the control chip embodiments of the storage system, and will not be repeated here.

Some embodiments of the present disclosure provide an electronic device including the memory.

In an exemplary embodiment of the present disclosure, any of the aforementioned embodiments of the storage cell, the storage array and the data writing and data reading method thereof are applicable to the control chip embodiments of the storage system, and will not be repeated here.

It may be understood by those of ordinary skills in the art that all or some acts in a method and function modules/units in a system and an apparatus in the disclosure may be implemented as software, firmware, hardware, or an appropriate combination thereof. In a hardware implementation, division of the function modules/units mentioned in the above description is not always corresponding to division of physical assemblies. For example, a physical assembly may have multiple functions, or a function or an act may be executed by several physical assemblies in cooperation. Some assemblies or all assemblies may be implemented as software executed by a processor such as a digital signal processor or a microprocessor, or implemented as hardware, or implemented as an integrated circuit such as an application specific integrated circuit. Such software may be distributed in a computer-readable medium, and the computer-readable medium may include a computer storage medium (or a non-transitory medium) and a communication medium (or a transitory medium). As known to those of ordinary skills in the art, a term computer storage medium includes volatile and nonvolatile, and removable and irremovable media implemented in any method or technology for storing information (for example, computer-readable instructions, a data structure, a program module, or other data). The computer storage medium includes, but is not limited to, RAM, ROM, EEPROM, a Flash RAM, or another memory technology, CD-ROM, a Digital Versatile Disk (DVD) or another optical disk storage, a magnetic box, a magnetic tape, magnetic disk storage or another magnetic storage apparatus, or any other medium that may be used for storing desired information and may be accessed by a computer. In addition, it is known to those of ordinary skills in the art that the communication medium usually includes computer-readable instructions, a data structure, a program module, or other data in a modulated data signal of, such as, a carrier or another transmission mechanism, and may include any information delivery medium.

1. A storage cell, comprising:
a first transistor, configured as a read transistor; and,
a second transistor, configured as a write transistor;
wherein, the first transistor comprises a first electrode, a second electrode, a third electrode and a fourth electrode; the third electrode is a first gate, and the fourth electrode is a second gate;
the second transistor comprises a fifth electrode, a sixth electrode and a seventh electrode; the seventh electrode is a third gate;
the first electrode is configured to be connected to a read bit-line, the second electrode is configured to be connected to a reference signal, the first gate is configured to be connected to a read word-line, and the second gate is configured to be connected to the fifth electrode;
the sixth electrode is configured to be connected to a write bit-line, and the third gate is configured to be connected to a write word-line.

2. The storage cell according to claim 1, wherein the first electrode and the sixth electrode share one electrode, and are configured to be connected to different bit-lines or to a same bit-line.

3. The storage cell according to claim 2, wherein the different bit-lines are the read bit-line and the write bit-line; and the same bit-line serves as both the read bit-line and the write bit-line.

4. The storage cell according to claim 1, wherein the first gate and the second gate are gates independent of each other, and the first gate is configured to control a read operation of the read transistor; the second gate is configured to write an electrical signal to a storage node through the write transistor as the storage node of the storage cell.

5. A storage array, comprising:
a write word-line;
a read word-line;
a write bit-line;
a read bit-line; and,
a plurality of storage cells according to claim 1;
wherein, a storage cell comprises the first transistor and the second transistor; the first transistor comprises the first electrode, the second electrode, the third electrode and the fourth electrode; the third electrode is the first gate, and the fourth electrode is the second gate;
the second transistor comprises the fifth electrode, the sixth electrode and the seventh electrode; the seventh electrode is the third gate;
the first electrode is connected to the read bit-line, the second electrode is configured to be connected with the reference signal, the first gate is connected to the read word-line, and the second gate is connected to the fifth electrode;
the sixth electrode is connected to the write bit-line, and the third gate is connected to the write word-line.

6. The storage array according to claim 5, wherein,
the first electrode and the sixth electrode share one electrode, the write bit-line and the read bit-line share one bit-line, and the shared electrode is connected to the shared bit-line.

7. A storage array, comprising:
a write word-line;
a read word-line;
a shared bit-line; and,
a plurality of storage cells according to claim 1;
wherein, a storage cell comprises the first transistor and the second transistor; the first transistor comprises the first electrode, the second electrode, the third electrode and the fourth electrode; the third electrode is the first gate, and the fourth electrode is the second gate;
the second transistor comprises the fifth electrode, the sixth electrode and the seventh electrode; the seventh electrode is the third gate;
both the first electrode and the sixth electrode are connected to the shared bit-line, the second electrode is configured to be connected with the reference signal, the first gate is connected to the read word-line, and the second gate is connected to the fifth electrode;
the third gate is connected to the write word-line.

8. A storage system, comprising:
a plurality of storage arrays according to claim 5; and,
a plurality of amplifiers;
wherein, each amplifier is an amplifier shared by two adjacent storage arrays; the amplifier is configured to amplify storage data read from the storage cell in the storage array, wherein the storage data is sensed in a sensing stage, and write the amplified storage data back to a storage node of the storage cell in a refresh stage.

9. The storage system according to claim 8, wherein the amplifier is a voltage amplifier or a current amplifier;
input terminals of two differential input signals of the amplifier are respectively connected with two different read bit-lines, and the two different read bit-lines are respectively from adjacent storage arrays;
one of the input terminals of the two differential input signals is an input terminal for the storage data read by the read bit-line, and the other input terminal is a reference signal terminal of the differential input signals of the amplifier.

10. A data writing method, which is based on the storage array according to claim 7, and the method comprising:
for a storage cell, to which data needs to be written, in a selected row of storage arrays in the storage array, inputting a gate voltage to a second transistor of the storage cell through a write word-line of the storage cell, to enable the second transistor as a write transistor to be turned on; and
inputting data to be written to the turned-on second transistor through a write bit-line or a shared bit-line of the storage cell, to enable a voltage corresponding to the data to be stored in a second gate of a first transistor connected to the second transistor, wherein the second gate is configured as a storage node of the storage cell, and the first transistor is a read transistor.

11. The data writing method according to claim 10, further comprising:
inputting a voltage different from a turned-on voltage of a third gate of a selected row of storage cells to a write word-line of each unselected row of storage cells in the storage array, to enable a second transistor of a storage cell to which data does not need to be written to be turned off.

12. A data reading method, which is based on the storage array according to claim 7, and the method comprising:
in a data read operation stage, inputting a first voltage to a read word-line connected to a first transistor of a storage cell, from which data needs to be read, in a selected row of storage cells in the storage array; wherein, the first voltage is between a first threshold voltage and a second threshold voltage, and the first threshold voltage is a turned-on threshold voltage of the first transistor when data “1” is stored to the storage cell; the second threshold voltage is a turned-on threshold voltage of the first transistor when data “0” is stored to the storage cell;
determining read data of the storage cell to be “1” when a change in a voltage of the read bit-line connected to the first transistor is detected and a value of the change is greater than or equal to a preset first voltage change threshold, and determining the read data of the storage cell be “0” when the voltage of the read bit-line connected to the first transistor does not change, or a value of a change of the read bit-line connected to the first transistor is less than or equal to a preset second voltage change threshold.

13. The data reading method according to claim 12, wherein a pre-charging stage is further comprised prior to the data read operation stage, the method further comprises:
pre-charging the read bit-line or the shared bit-line, to enable a voltage on the read bit-line to be higher than a voltage provided at a reference signal terminal in differential input signal input terminals of an amplifier.

14. The data reading method according to claim 12, further comprising:
during reading of data stored in a second transistor of a storage cell, from which data needs to be read, in the storage array, inputting a voltage to a read word-line of a storage cell, from which data does not to be read, in the storage array, wherein the input voltage is different from an input voltage of a read word-line of a first transistor of a storage cell from which data needs to be read, to enable the first transistor of the storage cell from which data needs to be read, to be turned off;
wherein, the read word-line of the storage cell from which data does not need to be read is different from the read word-line of the first transistor of the storage cell from which data needs to be read.

15. The data reading method according to claim 12, further comprising: performing data refresh in a refresh stage;
wherein the performing data refresh in the refresh stage comprises: sensing the storage data in the storage cell, amplifying the storage data by an amplifier, and writing the amplified storage data back into a storage node of the storage cell.

16. The data reading method according to claim 15, further comprising:
during a process of refreshing the storage data of the second transistor, inputting a voltage to a write word-line of a storage cell, whose storage data does not need to be refreshed, to enable a second transistor of the storage cell to which data does not need to be written to be turned off;
wherein the write word-line connected to the storage cell that needs to be refreshed is different from the write word-line of the storage cell whose storage data does not need to be refreshed.

17. A control chip of a storage array, configured to perform the data writing method according to claim 10.

18. A control chip of a storage array, configured to perform the data reading method according to claim 12.

19. A memory, comprising the storage array according to claim 5.

20. A storage system, comprising:
a plurality of storage arrays according to claim 7; and,
a plurality of amplifiers;
wherein, each amplifier is an amplifier shared by two adjacent storage arrays; the amplifier is configured to amplify storage data read from the storage cell in the storage array, wherein the storage data is sensed in a sensing stage, and write the amplified storage data back to a storage node of the storage cell in a refresh stage.
